(19) United States
(12) Patent Application Publication
(10) Pub. No.: US 2024/0215372 A1
(43) Pub. Date: Jun. 27, 2024

(54) DISPLAY PANELS AND DISPLAY APPARATUSES

(71) Applicants: Beijing BOE Display Technology Co., Ltd., Beijing (CN); BOE Technology Group Co., Ltd., Beijing (CN)

(72) Inventors: Yujie LIU, Beijing (CN); Song YANG, Beijing (CN); Ge SHI, Beijing (CN); Pengxia LIANG, Beijing (CN); Zheng FANG, Beijing (CN); Yanliu SUN, Beijing (CN); Jiahui HAN, Beijing (CN); Qian WU, Beijing (CN); Hongpeng LI, Beijing (CN)

(21) Appl. No.: 17/795,074

(22) PCT Filed: Jun. 22, 2021
(86) PCT No.: PCT/CN2021/101490

§ 371 Date: Jul. 25, 2022

(51) Int. Cl. H10K 59/38; H10K 59/80

(52) U.S. Cl. CPC H10K 59/38; H10K 59/8731; H10K 59/877; H10K 59/879; H10K 59/8792

(57) ABSTRACT

Disclosed are display panels and display apparatuses. A display panel includes a base substrate, a light-emitting layer located on the base substrate, an insulating material structure, a color conversion layer, and an auxiliary layer. The light-emitting layer includes a plurality of light-emitting structures arranged at intervals. The insulating material structure is located on a side of the light-emitting layer facing away from the base substrate, and includes organic and inorganic layers arranged alternately. The color conversion layer is located on a side of the insulating material structure facing away from the base substrate, and includes a plurality of color conversion portions with a shading portion located between adjacent color conversion portions. The auxiliary layer has an orthographic projection on the base substrate covering an orthographic projection of the shading portion on the base substrate, the auxiliary layer is in direct contact with adjacent organic and inorganic layers in the insulating material structure, respectively, and the auxiliary layer has a refractive index that is less than a refractive index of the organic layer in direct contact with the auxiliary layer and less than a refractive index of the inorganic layer in direct contact with the auxiliary layer.

### CROSS-REFERENCE TO RELATED APPLICATIONS

The present application is the U.S. national phase of PCT Application No. PCT/CN2021/101490 filed on Jun. 22, 2021, which is incorporated herein by reference in its entirety.

### TECHNICAL FIELD

The present application relates to the field of display technology, and in particular to a display panel and a display apparatus.

### BACKGROUND

A display panel includes: an organic light-emitting material; and a color conversion layer located above the organic light-emitting material and including a quantum dot material. This display panel has advantages such as high resolution, high color gamut, high color purity, and no dependence on viewing angle.

However, there is a relatively large distance between a light-emitting layer and the color conversion layer in the above display panel, and part of light emitted by a sub-pixel may be incident on an area of the color conversion layer corresponding to an adjacent sub-pixel, resulting in cross-color between adjacent sub-pixels and thus reducing a color gamut of the display panel.

### SUMMARY

According to a first aspect of embodiments of the present application, there is provided a display panel. The display panel includes:
a base substrate;
a light-emitting layer located on the base substrate, and including a plurality of light-emitting structures arranged at intervals;
an insulating material structure located on a side of the light-emitting layer facing away from the base substrate, and including organic and inorganic layers arranged alternately;
a color conversion layer located on a side of the insulating material structure facing away from the base substrate, and including a plurality of color conversion portions with a shading portion located between adjacent color conversion portions; and
an auxiliary layer having an orthographic projection on the base substrate covering an orthographic projection of the shading portion on the base substrate, the auxiliary layer being in direct contact with adjacent organic and inorganic layers in the insulating material structure, respectively, and the auxiliary layer having a refractive index that is less than a refractive index of the organic layer in direct contact with the auxiliary layer and less than a refractive index of the inorganic layer in direct contact with the auxiliary layer.

In an embodiment, the insulating material structure includes an encapsulation layer, and the encapsulation layer includes at least two inorganic layers and at least one organic layer; and the auxiliary layer is located between the organic layer of the encapsulation layer and the inorganic layer provided on a side of the organic layer close to the base substrate.

In an embodiment, the encapsulation layer includes a first inorganic layer, an encapsulation organic layer located on the first inorganic layer, and a second inorganic layer located on the encapsulation organic layer, the first inorganic layer is in direct contact with the light-emitting structures, and the auxiliary layer is located between the first inorganic layer and the encapsulation organic layer.

In an embodiment, the auxiliary layer is located between adjacent organic and inorganic layers in the insulating material structure; and the orthographic projection of the auxiliary layer on the base substrate covers an orthographic projection of the color conversion layer on the base substrate.

In an embodiment, the refractive index of the auxiliary layer is less than or equal to 1.4.

In an embodiment, the organic layer in direct contact with the auxiliary layer is provided with one or more hollow portions, in which the auxiliary layer is disposed.

In an embodiment, the organic layer in direct contact with the auxiliary layer is an adhesive layer, and the adhesive layer is in direct contact with the color conversion layer.

In an embodiment, the orthographic projection of the auxiliary layer on the base substrate coincides with the orthographic projection of the shading portion on the base substrate.

In an embodiment, the auxiliary layer and the adhesive layer have a same thickness.

In an embodiment, a material of the auxiliary layer includes nitrogen or an inert gas.

In an embodiment, a material of the auxiliary layer includes at least one of a metal fluoride, or a substituted or unsubstituted polyacrylate.

In an embodiment, the auxiliary layer includes a photonic crystal structure, which includes a plurality of columnar structures arranged in an array.

In an embodiment, a first distance between centers of adjacent two of the columnar structures ranges from 100 nm to 300 nm.

In an embodiment, a minimum distance between adjacent two of the columnar structures is a second distance, and a ratio of a difference between the first distance and the second distance to the first distance ranges from 0.2 to 0.8.

In an embodiment, the color conversion portions correspond to the light-emitting structures one-to-one, and an orthographic projection of the color conversion portions on the base substrate covers an orthographic projection of the light-emitting structures on the base substrate.

In an embodiment, each of the light-emitting structures in the light-emitting layer emits blue light; and the color conversion portion includes: a red color conversion portion including a red quantum dot and a light-scattering particle; a green color conversion portion including a green quantum dot and a light-scattering particle; and a light-transmissive portion including a light-scattering particle.

In an embodiment, the display panel further includes a filter layer located on a side of the color conversion layer facing away from the base substrate, where the filter layer includes a black matrix and a plurality of filter portions, the plurality of filter portions correspond to the plurality of light-emitting structures one-to-one, and the orthographic projection of the shading portion on the base substrate coincides with an orthographic projection of the black matrix on the base substrate.

According to a second aspect of embodiments of the present application, there is provided a display apparatus including the above display panel.

Embodiments of the present application may mainly provide the following technical effects.

With the display panel and display apparatus according to embodiments of the present application, the orthographic projection of the auxiliary layer on the base substrate covers the orthographic projection of the shading portion on the base substrate. The auxiliary layer is in direct contact with adjacent organic and inorganic layers in the insulating material structure, respectively, and the refractive index of the auxiliary layer is less than the refractive index of the organic layer in direct contact with the auxiliary layer, and is less than the refractive index of the inorganic layer in direct contact with the auxiliary layer. In this case, at least part of light emitted by the light-emitting structure with a larger exit angle is totally reflected at an interface between the auxiliary layer and a film layer adjacent to the auxiliary layer and located on a side of the auxiliary layer close to the base substrate, such that the amount of light entering the color conversion portion corresponding to an adjacent light-emitting structure among the light emitted by the light-emitting structure with a larger exit angle is reduced, which helps to avoid cross-color between adjacent light-emitting structures, improve display brightness of the light-emitting structures, and improve a color gamut of the display panel.

### BRIEF DESCRIPTION OF DRAWINGS

FIG. 1 is a schematic diagram illustrating a three-dimensional structure of a display panel according to an exemplary embodiment of the present application.

FIG. 2 is a schematic structural diagram illustrating a display panel according to an exemplary embodiment of the present application.

FIG. 3 is a schematic structural diagram illustrating a display panel according to another exemplary embodiment of the present application.

FIG. 4 is a cross-sectional view of the display panel shown in FIG. 2 or FIG. 3 taken along AA.

FIG. 5 is another cross-sectional view of the display panel shown in FIG. 2 or FIG. 3 taken along AA.

FIG. 6 shows a comparison between a graph illustrating light intensity versus light wavelength for light emitted by a light-emitting structure and a graph illustrating light intensity versus light wavelength for light absorbed by a quantum dot according to an exemplary embodiment of the present application.

FIG. 7 is a plan view illustrating a photonic crystal structure according to an exemplary embodiment of the present application.

FIG. 8 is a cross-sectional view of the photonic crystal structure shown in FIG. 7 taken along BB.

FIG. 9 is a graph illustrating light intensity versus light-emitting angle of blue light emitted by a light-emitting structure according to an exemplary embodiment of the present application.

FIG. 10 is a graph illustrating color gamut versus light-leakage ratio of a display panel according to an exemplary embodiment of the present application.

### DETAILED DESCRIPTION

Exemplary embodiments will be described herein in detail, examples of which are illustrated in the drawings. When the following description involves the drawings, like numerals in different drawings indicate like or similar elements unless otherwise indicated. Embodiments described in the following exemplary embodiments do not represent all embodiments consistent with the present application. Rather, they are merely examples of apparatuses and methods consistent with some aspects of the present application as detailed in the appended claims.

The terminology used in the present application is for the purpose of describing particular embodiments only, and is not intended to limit the present application. As used in the present application and the appended claims, terms determined by “a”, “the” and “said” in their singular forms are intended to include plural forms as well, unless clearly indicated otherwise in the context. It should also be understood that the term “and/or” as used herein refers to and includes any or all possible combinations of one or more of the associated listed items.

It should be understood that though terms first, second, third, etc. may be used in the present application to describe various information, such information should not be limited to these terms. These terms are only used to distinguish the same type of information from each other. For example, the first information may also be referred to as the second information, and similarly, the second information may also be referred to as the first information, without departing from the scope of the present application. Depending on the context, the word “if” as used herein may be interpreted as “upon”, “when” or “in response to determining”.

Embodiments of the present application provide a display panel and a display apparatus. The display panel and the display apparatus according to embodiments of the present application will be described in detail below with reference to the accompanying drawings. Features in the embodiments described below may complement each other or be combined with each other without conflict.

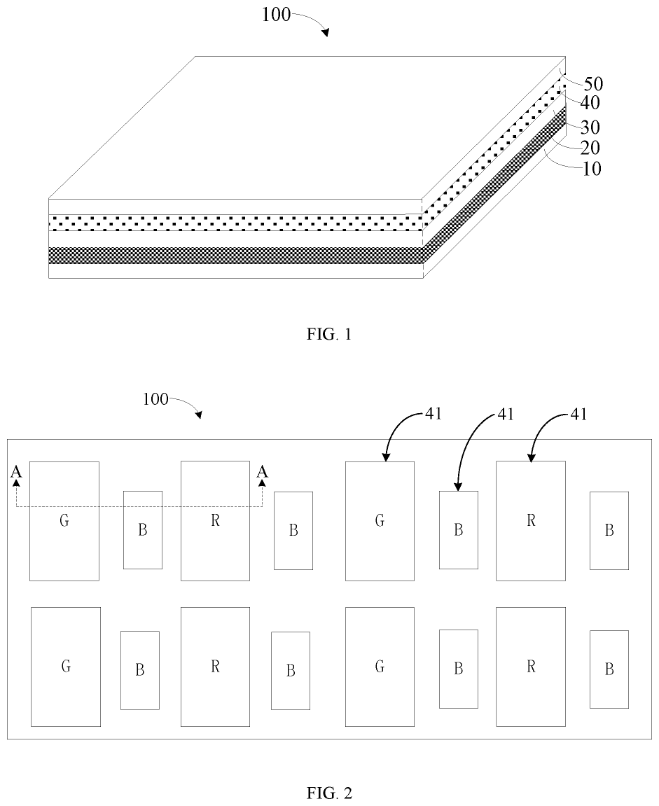

Embodiments of the present application provide a display panel. With reference to FIGS. 1 to 5, the display panel includes a base substrate 10, a light-emitting layer 20, an insulating material structure 30, a color conversion layer 40, and an auxiliary layer 60.

The light-emitting layer 20 is located on the base substrate 10, and includes a plurality of light-emitting structures 201 arranged at intervals. The insulating material structure 30 is located on a side of the light-emitting layer 20 facing away from the base substrate 10. The insulating material structure 30 includes organic and inorganic layers arranged alternately. The color conversion layer 40 is located on a side of the insulating material structure 30 facing away from the base substrate 10, and includes a plurality of color conversion portions 41 with a shading portion 42 located between adjacent color conversion portions 41. In an embodiment, the color conversion layer 40 is provided with a plurality of openings, in which the color conversion portions 41 are respectively disposed.

An orthographic projection of the auxiliary layer 60 on the base substrate 10 covers an orthographic projection of the shading portion 42 on the base substrate 10. The auxiliary layer 60 is in direct contact with adjacent organic and inorganic layers in the insulating material structure 30, respectively, and the auxiliary layer 60 has a refractive index that is less than a refractive index of the organic layer in direct contact with the auxiliary layer 60 and less than a refractive index of the inorganic layer in direct contact with the auxiliary layer 60.

With the display panel according to embodiments of the present application, the orthographic projection of the auxiliary layer 60 on the base substrate 10 covers the orthographic projection of the shading portion 42 on the base substrate 10. The auxiliary layer 60 is in direct contact with adjacent organic and inorganic layers in the insulating material structure 30, respectively, and the refractive index of the auxiliary layer 60 is less than the refractive index of the organic layer in direct contact with the auxiliary layer 60, and is less than the refractive index of the inorganic layer in direct contact with the auxiliary layer 60. In this case, at least part of light emitted by the light-emitting structure 201 with a larger exit angle is totally reflected at an interface between the auxiliary layer 60 and a film layer adjacent to the auxiliary layer and located on a side of the auxiliary layer close to the base substrate, such that the amount of light entering the color conversion portion corresponding to an adjacent light-emitting structure 201 among the light emitted by the light-emitting structure 201 with a larger exit angle is reduced, which helps to avoid cross-color between adjacent light-emitting structures, improve display brightness of the light-emitting structures, and improve a color gamut of the display panel.

In the embodiments of the present application, “adjacent organic and inorganic layers in the insulating material structure 30” means that the organic layer is in direct contact with the inorganic layer, or that there is another film layer between the organic layer and the inorganic layer, which is not part of the insulating material structure 30. The insulating material structure 30 includes organic and inorganic layers arranged alternately, which means that an organic layer and an inorganic layer are arranged alternately in the insulating material structure 30, that is, one inorganic layer is arranged between two adjacent organic layers, and one organic layer is arranged between two adjacent inorganic layers.

In an embodiment, the base substrate 10 may be a rigid substrate, which may be made of glass, metal, or the like. In other embodiments, the base substrate 10 may be a flexible substrate, which may be made of one or more of PI (polyimide), PET (polyethylene terephthalate), and PC (polycarbonate).

In an embodiment, the display panel further includes a pixel driving circuit layer disposed between the base substrate 10 and the light-emitting layer 20. The pixel driving circuit layer includes a pixel driving circuit for driving the light-emitting structure. The pixel driving circuit includes a thin film transistor 90. The thin film transistor 90 includes an active layer 91, a gate electrode 92 located on a side of the active layer 91 facing away from the base substrate 10, a first pole 93, and a second pole 94. One of the first pole 93 and the second pole 94 is a source electrode, and the other is a drain electrode. The pixel driving circuit may further include a capacitor (not shown).

The pixel driving circuit layer further includes a gate insulation layer 81, an interlayer dielectric layer 82, and a planarization layer 83. The gate insulation layer 81 is located between the active layer 91 and the gate electrode 92. The interlayer dielectric layer 82 is located on a side of the gate electrode 92 facing away from the base substrate 10, and the first pole 93 and the second pole 94 are electrically connected with the active layer 91 through through-holes penetrating the gate insulation layer 81 and the interlayer dielectric layer 82. The planarization layer 83 is located on a side of the first pole 93 and the second pole 94 facing away from the base substrate 10, and covers the exposed interlayer dielectric layer 82.

In an embodiment, the light-emitting layer 20 includes a plurality of light-emitting structures 201 arranged at intervals. The light-emitting structures 201 in the light-emitting layer 20 may emit light with the same color, for example, each light-emitting structure 201 in the light-emitting layer 20 may emit blue light. Light with the same color emitted by the light-emitting layer 20 is converted into light with multiple colors when passing through the color conversion layer, enabling a color display of the display panel.

In an embodiment, the light-emitting structure 201 is located on a side of the planarization layer 83 facing away from the base substrate 10. The light-emitting structure 201 includes a first electrode 21, an organic light-emitting material layer 22 located on a side of the first electrode 21 facing away from the base substrate 10, and a second electrode 23 located on a side of the organic light-emitting material layer 22 facing away from the base substrate 10. The first electrode 21 and the second electrode 23 are in direct contact with the organic light-emitting material layer 22, respectively. The first electrode 21 may be an anode, and the second electrode 23 may be a cathode. The second electrode 23 of the individual light-emitting structures 201 may be a whole-surface electrode connected into one piece. The first electrode 21 is electrically connected with the first pole 93 of the thin film transistor 90 through a through-hole penetrating the planarization layer 83.

In some embodiments, the display panel 100 has a top-emission structure with the first electrode 21 being a reflective electrode and the second electrode 23 being a light-transmissive electrode.

In an embodiment, the display panel 100 further includes a pixel definition layer 84, which is provided with a plurality of pixel openings. The pixel openings may correspond to the light-emitting structures 201 one-to-one. The first electrode 21 is located below the pixel definition layer 84, and the pixel opening exposes a portion of the first electrode 21 of a corresponding light-emitting structure 201. At least a portion of the organic light-emitting material layer 22 of the light-emitting structure 201 is located in a corresponding pixel opening.

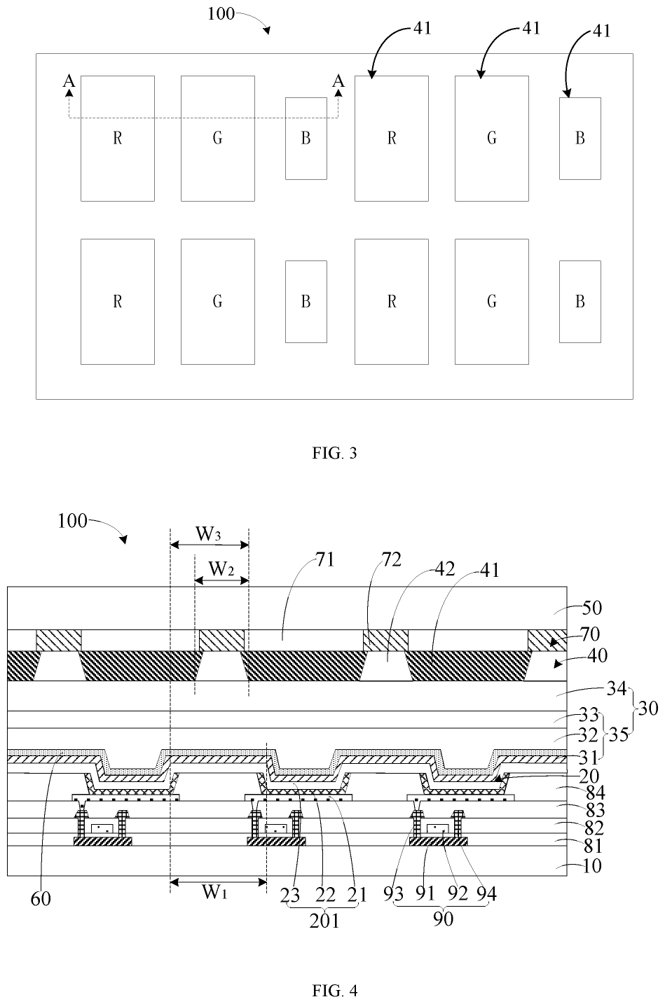

In an embodiment, the color conversion layer 40 includes a plurality of color conversion portions 41. Referring to FIG. 2 and FIG. 3, the color conversion portion 41 includes a red color conversion portion R, a green color conversion portion G, and a light-transmissive portion B. The red color conversion portion R converts blue light emitted by the light-emitting structure 201 into red light, the green color conversion portion G converts the blue light emitted by the light-emitting structure 201 into green light, and the light-transmissive portion B may allow transmission of the blue light emitted by the light-emitting structure 201. FIG. 2 and FIG. 3 merely illustrate two exemplary arrangements of the plurality of color conversion portions 41. In other embodiments, the arrangement of the plurality of color conversion portions 41 of the color conversion layer 40 may be different from those shown in FIG. 2 and FIG. 3.

In an embodiment, the color conversion portions 41 correspond to the light-emitting structures 201 one-to-one, and an orthographic projection of the color conversion portions 41 on the base substrate 10 covers an orthographic projection of the light-emitting structures 201 on the base substrate 10. In this way, a larger amount of light emitted by the light-emitting structure 201 may be incident on a corresponding color conversion portion 41, which helps to improve the utilization of light.

The orthographic projection of the color conversion portions 41 on the base substrate 10 covers the orthographic projection of the light-emitting structures 201 on the base substrate 10, which means that an area of an orthographic projection of the color conversion portion 41 on the base substrate 10 is larger than an area of an orthographic projection of a corresponding light-emitting structure 201 on the base substrate 10, or that the orthographic projection of the color conversion portion 41 on the base substrate 10 substantially coincides with the orthographic projection of the corresponding light-emitting structure 201 on the base substrate 10. Preferably, the area of the orthographic projection of the color conversion portion 41 on the base substrate 10 is larger than the area of the orthographic projection of the corresponding light-emitting structure 201 on the base substrate 10, such that a larger amount of light emitted by the light-emitting structure 201 may be incident on the corresponding color conversion portion 41.

In an embodiment, the red color conversion portion includes a red quantum dot and a light-scattering particle dispersed in the red quantum dot. The green color conversion portion includes a green quantum dot and a light-scattering particle dispersed in the green quantum dot. The light-transmissive portion includes a light-transmissive material and a light-scattering particle dispersed in the light-transmissive material. The light-transmissive material may have a relatively high light transmittance, for example, greater than 80%. The red quantum dot may convert blue light emitted by the light-emitting structure 201 into red light, and the green quantum dot may convert the blue light emitted by the light-emitting structure 201 into green light. The light-transmissive portion does not change a color of incident light. By including the light-scattering particle in the color conversion portion, light may be distributed more uniformly when it is emitted through the color conversion portion, which is conducive to improving the uniformity of the display brightness of the display panel.

Further, each of the color conversion portions includes a plurality of light-scattering particles uniformly distributed therein. In this way, the uniformity of the display brightness of the display panel can be further improved.

In an embodiment, the display panel 100 further includes a filter layer 70 located on a side of the color conversion layer 40 facing away from the base substrate 10. The filter layer 70 includes a black matrix 72 and a plurality of filter portions 71 with the black matrix 72 being located between adjacent filter portions 71. The plurality of filter portions 71 correspond to the plurality of light-emitting structures 201 one-to-one, and an orthographic projection of the shading portion 42 on the base substrate 10 may coincide with an orthographic projection of a corresponding black matrix 72 on the base substrate 10. A width of a cross-section of the shading portion 42 in a longitudinal direction (a direction in which film layers of the display panel are stacked) on a side close to the base substrate is greater than a width of the cross-section of the shading portion 42 in the longitudinal direction on a side away from the base substrate. The orthographic projection of the shading portion 42 on the base substrate 10 may coincide with the orthographic projection of the corresponding black matrix 72 on the base substrate 10, which means that the width of the cross-section of the shading portion 42 in the longitudinal direction on the side close to the base substrate may be substantially the same as a width of a cross-section of the corresponding black matrix 72 in the longitudinal direction. In this way, almost all of light emitted through the color conversion portion 41 may exit through the corresponding filter portion 71.

In some embodiments, the filter portion 71 of the filter layer 70 includes a red filter portion, a green filter portion, and a blue filter portion. In particular, an orthographic projection of the red filter portion on the base substrate 10 substantially coincides with an orthographic projection of a corresponding red color conversion portion on the base substrate 10, an orthographic projection of the green filter portion on the base substrate 10 substantially coincides with an orthographic projection of a corresponding green color conversion portion on the base substrate 10, and an orthographic projection of the blue filter portion on the base substrate 10 substantially coincides with an orthographic projection of a corresponding light-transmissive portion on the base substrate 10. The red filter portion may filter out non-red light from the incident light, the green filter portion may filter out non-green light from the incident light, and the blue filter portion may filter out non-blue light from the incident light. Therefore, the filter layer 70 may be provided to improve the purity of exit light.

FIG. 6 shows a comparison between a graph illustrating light intensity versus light wavelength for light emitted by a light-emitting structure and a graph illustrating light intensity versus light wavelength for light absorbed by a quantum dot. Curve a represents a graph illustrating light intensity versus light wavelength for blue light emitted by the light-emitting structure, curve b represents a graph illustrating light intensity versus light wavelength for blue light absorbed by a green quantum dot, and curve c represents a graph illustrating light intensity versus light wavelength for blue light absorbed by a red quantum dot. As can be seen from FIG. 6, the light intensity of the blue light emitted by the light-emitting structure is stronger than that of the blue light absorbed by the green quantum dot, and the light intensity of the blue light emitted by the light-emitting structure is stronger than that of the blue light absorbed by the red quantum dot. The filter layer 70 may be provided to filter out the blue light that cannot be absorbed by the quantum dots, thereby improving the purity of the exit light.

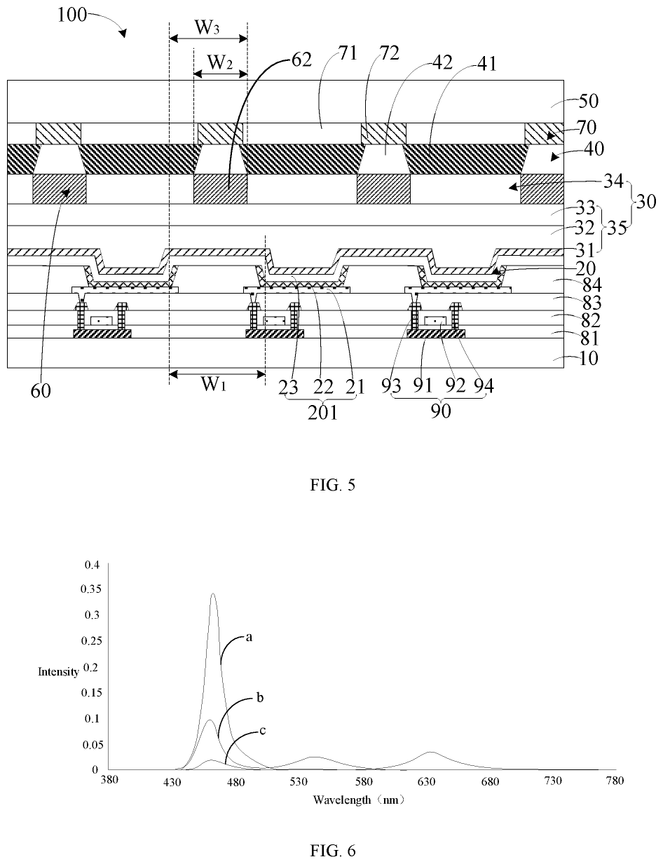

In an embodiment, referring again to FIGS. 4 and 5, the insulating material structure 30 includes an encapsulation layer 35, and the encapsulation layer 35 includes at least two inorganic layers and at least one organic layer. The inorganic and organic layers of the encapsulation layer 35 are arranged alternately, a film layer in the encapsulation layer with the minimum distance from the base substrate is an inorganic layer, and a film layer in the encapsulation layer with the maximum distance from the base substrate is an inorganic layer. The inorganic layer may be made of silicon oxide, silicon nitride, or silicon oxynitride. The organic layer may be made of, for example, an acrylic material. The organic layer may wrap particles on a surface of the inorganic layer located on a side of the organic layer close to the base substrate, so as to avoid the risk of film rupture in the subsequently formed inorganic layer.

In an embodiment, the insulating material structure 30 further includes: an adhesive layer 34 located on a side of the encapsulation layer 35 facing away from the base substrate 10; and a substrate 50 located on a side of the filter layer 70 facing away from the base substrate 10. The substrate 50 may have a relatively high light transmittance.

Individual film layers of the display panel may be divided into a display module and a color conversion module. The display module includes the base substrate 10, the pixel driving circuit layer, the light-emitting layer 20, and the encapsulation layer 35. The color conversion module includes the substrate 50, the filter layer 70, the color conversion layer 40, and the adhesive layer 34. The auxiliary layer 60 may be disposed in the display module or in the color conversion module.

In the process of preparing the display panel, the display module and the color conversion module are first formed. The display module is prepared by sequentially forming the pixel driving circuit layer, the light-emitting layer 20, and the encapsulation layer 35 on the base substrate 10. The color conversion module is prepared by sequentially forming the filter layer 70, the color conversion layer 40, and the adhesive layer 34 on the substrate 50. The auxiliary layer 60 may be formed in the process of preparing the display module, or be formed in the process of preparing the color conversion module. After that, the color conversion module and the display module are cell-assembled, such that the color conversion module and the display module are bonded together by the adhesive layer 34.

When the color conversion layer 40 is formed in the process of preparing the color conversion module, the shading portion 42 is first formed, and then the color conversion portions. The shading portion 42 is formed by forming a shading material film on a whole side, and then etching the shading material film. Due to a large thickness of the shading material film, a side of the shading portion 42 close to the substrate shrinks inwardly during the etching process, such that a size of the shading portion 42 in a transverse direction (perpendicular to the direction in which the film layers of the display panel are stacked) gradually increases from the side close to the substrate to a side away from the substrate.

In an embodiment, the auxiliary layer 60 is located between adjacent organic and inorganic layers in the insulating material structure 30, and the orthographic projection of the auxiliary layer 60 on the base substrate 10 covers an orthographic projection of the color conversion layer 40 on the base substrate 10. In this way, the auxiliary layer 60 may not be patterned, which helps to simplify the preparation process.

In an embodiment, the auxiliary layer 60 is located between the organic layer of the encapsulation layer 35 and the inorganic layer on a side of the organic layer close to the base substrate 10. Since the refractive index of the organic layer is less than that of the inorganic layer, if light is directly incident from the inorganic layer to an interface between the inorganic layer and the adjacent organic layer, an exit angle of the light increases and a transmission distance of the light in the transverse direction (parallel to an extension direction of the base substrate) increases, which may lead to an increase in the degree of cross-color in the display panel. By providing the auxiliary layer 60 between the organic layer and the inorganic layer on the side of the organic layer close to the base substrate 10, part of light emitted from the inorganic layer with a larger exit angle is totally reflected at an interface between the inorganic layer and the auxiliary layer, that is, part of the light with a larger exit angle has been totally reflected before entering the organic layer, which can reduce the amount of light entering the organic layer and thus the resulting cross-color.

In an embodiment, the encapsulation layer 35 may include one organic layer, or two or more organic layers. When the encapsulation layer 35 includes two or more organic layers, one of the organic layers is provided with the auxiliary layer 60 on a side close to the base substrate, or each of the organic layers is provided with the auxiliary layer 60 on a side close to the base substrate.

In an embodiment, referring again to FIG. 4, the encapsulation layer 35 includes three film layers, namely a first inorganic layer 31, an encapsulation organic layer 32 on a side of the first inorganic layer 31 facing away from the base substrate 10, and a second inorganic layer 33 on a side of the encapsulation organic layer 32 facing away from the base substrate 10. The first inorganic layer 31 is in direct contact with the light-emitting structures 201, and the auxiliary layer 60 is located between the first inorganic layer 31 and the encapsulation organic layer 32. In this way, light emitted by the light-emitting structure 201 with a larger exit angle is totally reflected at an interface between the first inorganic layer 31 and the auxiliary layer 60, and may not enter the encapsulation organic layer with a lower refractive index and a larger thickness, such that a transmission distance of the light with a larger exit angle in the transverse direction can be shortened, cross-color between adjacent light-emitting structures can be more effectively avoided, and the color gamut of the display panel can be improved. Since the transmission distance of the light with a larger exit angle in the transverse direction is shortened, widths of the shading portion 42 and the black matrix 72 can be reduced, and thus an aperture ratio of the pixel opening can be increased, thereby increasing an effective display area of the display panel, while ensuring the same degree of cross-color between adjacent light-emitting structures.

In an exemplary embodiment, the first inorganic layer 31 may be made of silicon oxynitride, and the second inorganic layer 33 may be made of silicon nitride.

In an embodiment, the refractive index of the auxiliary layer 60 is less than or equal to 1.4. In this way, the degree of cross-color between adjacent light-emitting structures 201 can be effectively reduced. In some embodiments, the refractive index of the auxiliary layer 60 may be slightly greater than 1.4, for example, the refractive index of the auxiliary layer 60 may range from 1.35 to 1.45.

In some embodiments, the material of the auxiliary layer 60 includes at least one of a metal fluoride, or a substituted or unsubstituted polyacrylate. When the auxiliary layer 60 includes the above-mentioned material, the auxiliary layer 60 may have a lower refractive index, which can effectively avoid cross-color between adjacent light-emitting structures. The metal fluoride may include, for example, magnesium fluoride. The substituted or unsubstituted polyacrylate may include, for example, poly(1,1,1,3,3,3-hexafluoroisopropyl acrylate) (with a refractive index of 1.375), poly(2,2,3,3,4,4,4-heptafluorobutyl acrylate) (with a refractive index of 1.377), poly(2,2,3,3,4,4,4-heptafluorobutyl methacrylate) (with a refractive index of 1.383), poly(2,2,3,3,3-pentafluoropropyl acrylate) (with a refractive index of 1.389), poly(1,1,1,3,3,3-hexafluoroisopropyl methacrylate) (with a refractive index of 1.390), poly(2,2,3,4,4,4-hexafluorobutyl acrylate) (with a refractive index of 1.394), etc.

Further, when the auxiliary layer 60 includes the metal fluoride, the auxiliary layer 60 may have a thickness ranging from 5 nm to 20 nm. The thickness of the auxiliary layer 60 may be, for example, 5 nm, 10 nm, 15 nm, 20 nm, etc.

Further, when the auxiliary layer 60 includes the substituted or unsubstituted polyacrylate, the auxiliary layer 60 may have a thickness ranging from 2 μm to 4 μm. The thickness of the auxiliary layer 60 may be, for example, 2 μm, 2.5 μm, 3 μm, 3.5 μm, 4 μm, etc.

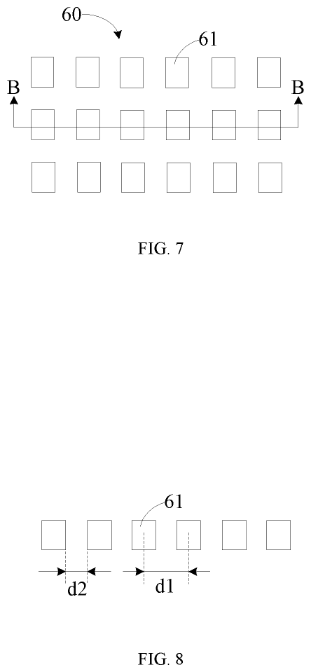

In another embodiment, referring to FIG. 7 and FIG. 8, the auxiliary layer 60 includes a photonic crystal structure, which includes a plurality of columnar structures 61 arranged in an array. The plurality of columnar structures 61 are arranged periodically. A distance between centers of two adjacent columnar structures 61 is a first distance, and the minimum distance between two adjacent columnar structures is a second distance.

A duty cycle of the photonic crystal structure may be calculated using the following equation (1):

$$f = ( {d}_{1} - {d}_{2} ) / {d}_{1} \qquad ( 1 )$$

where f indicates the duty cycle of the photonic crystal structure, d₁ indicates the first distance, and d₂ indicates the second distance.

An equivalent refractive index of the photonic crystal structure may be calculated using the following equation (2):

$$n = \sqrt{f {ε}_{1} + ( 1 - f ) {ε}_{2}} \qquad ( 2 )$$

where n indicates the equivalent refractive index of the photonic crystal structure, ε₁ indicates a dielectric constant of the columnar structure 61, and ε₂ indicates a dielectric constant of a gas between adjacent columnar structures 61. The gas between adjacent columnar structures 61 may be, for example, nitrogen or air, which has a dielectric constant of about 1.

In some embodiments, the first distance between centers of two adjacent columnar structures 61 may range from 100 nm to 300 nm. This can not only avoid more difficulty in preparation process due to too small first distance between centers of two adjacent columnar structures 61, but also avoid diffraction of light passing through the photonic crystal structure due to too large first distance between centers of two adjacent columnar structures 61. In some exemplary embodiments, the first distance between centers of two adjacent columnar structures 61 may be, for example, 100 nm, 150 nm, 200 nm, 250 nm, 300 nm, etc.

In some embodiments, a difference between the first distance and the second distance at different positions of the photonic crystal structure is relatively small, allowing the equivalent refractive indices at different positions of the photonic crystal structure to be relatively close.

In some embodiments, a ratio of the difference between the first distance and the second distance to the first distance may range from 0.2 to 0.8. In this way, the plurality of columnar structures may be distributed more uniformly in the photonic crystal structure, and there may be a relatively small difference in the equivalent refractive indices at different positions of the photonic crystal structure, which is more helpful to improve the uniformity of display brightness of the display panel in different areas. In some exemplary embodiments, the ratio of the difference between the first distance and the second distance to the first distance may be 0.2, 0.3, 0.4, 0.5, 0.6, 0.7, 0.8, etc.

In an exemplary embodiment, the columnar structure 61 is made of SiOx, which has a refractive index of about 1.5, and the duty cycle of the photonic crystal structure is 0.5, and the equivalent refractive index of the photonic crystal structure is calculated as 1.27 using the above equation (2). It can be seen that the equivalent refractive index of the photonic crystal structure is small, which can reduce the degree of cross-color between adjacent light-emitting structures 201.

In an embodiment, referring to FIG. 4, the insulating material structure 30 includes the first inorganic layer 31, the encapsulation organic layer 32, the second inorganic layer 33, and the adhesive layer 34 that are stacked in sequence, with the auxiliary layer 60 being located between the first inorganic layer 31 and the encapsulation organic layer 32.

In an exemplary embodiment, the first inorganic layer 31 has a refractive index n₁=1.8 and a thickness d₁=1 μm. The encapsulation organic layer 32 has a refractive index n₂=1.5 and a thickness d₂=8 μm. The second inorganic layer 33 has a refractive index n₃=1.9 and a thickness d₃=0.6 μm. The adhesive layer 34 has a refractive index n₄=1.5 and a thickness d₄=8 μm. A distance between two adjacent pixel openings on a side facing away from the base substrate 10 is W₁, a width of the shading portion 42 on a side facing the base substrate 10 is W₂, and a distance between an edge of the pixel opening on a side facing away from the base substrate 10 and an edge of a corresponding shading portion 42 away from that pixel opening is W₃, where the corresponding shading portion 42 to the pixel opening refers to a shading portion adjacent to the color conversion portion corresponding to the pixel opening and close to that edge of the pixel opening.

If the auxiliary layer 60 is not provided in the insulating material structure 30, when light emitted from an edge of a light-emitting structure 201 enters a color conversion portion corresponding to an adjacent light-emitting structure 201, the minimum incident angle of the light entering the first inorganic layer 31 is the minimum cross-color angle θ₁, an incident angle of the light entering the encapsulation organic layer 32 is θ₂, an incident angle of the light entering the second inorganic layer 33 is θ₃, and an incident angle of the light entering the adhesive layer 34 is θ₄. In this case, the refractive indices and thicknesses of individual film layers and the incident angles, as well as W₁, W₂, and W₃ satisfy the following relational expression (3) and equation (4).

$${n}_{1} sin {θ}_{1} = {n}_{2} sin {θ}_{2} = {n}_{3} sin {θ}_{3} = {n}_{4} sin {θ}_{4} \qquad ( 3 )$$

$${W}_{3} = \frac{{W}_{1} + {W}_{2}}{2} = {d}_{1} tan {θ}_{1} + {d}_{2} tan {θ}_{2} + {d}_{3} tan {θ}_{3} + {d}_{4} tan {θ}_{4} \qquad ( 4 )$$

As can be seen from the above equation (4), for given W₁, d₁, d₂, d₃ and d₄, the smaller θ₁ is, the smaller W₂ is, that is, the smaller the width of the shading portion 42 on the side facing the base substrate 10 is, the greater the aperture ratio of pixel in the display panel is.

During exit of light emitted by the light-emitting structure 201, part of the light is totally reflected at an interface between the first inorganic layer 31 and the encapsulation organic layer 32. A critical angle of total reflection is calculated as 56° using the above equations (3) and (4), that is, among the light emitted from an edge portion of the light-emitting structure, any light emitted from the first inorganic layer 31 at an exit angle greater than 56° may not exit from the first inorganic layer 31. However, due to a low refractive index of the encapsulation organic layer 32, a range of an exit angle of the light entering the encapsulation organic layer 32 becomes 0°˜90°. Part of the light exiting from the encapsulation organic layer 32 finally enters the color conversion portion corresponding to the adjacent light-emitting structure 201, resulting in cross-color between adjacent light-emitting structures. Even if the width of the shading portion 42 is increased, part of the light may enter the color conversion portion corresponding to the adjacent light-emitting structure 201, and an increase in the width of the shading portion 42 may lead to a reduction in the aperture ratio of the pixel. Therefore, the problem of cross-color between adjacent light-emitting structures 201 may not be solved by increasing the width of the shading portion.

In the embodiment shown in FIG. 4, the auxiliary layer 60 is provided between the first inorganic layer 31 and the encapsulation organic layer 32, and refractive indices of the first inorganic layer 31, the encapsulation organic layer 32, and the auxiliary layer 60, and the incident angles of light satisfy the following relational expression (5):

$${n}_{1} sin {θ}_{1} = {n}_{2} sin {θ}_{2} = {n}_{5} sin {θ}_{5} \qquad ( 5 )$$

where θ₅ indicates an incident angle of light incident to the auxiliary layer 60, and n₅ indicates a refractive index of the auxiliary layer 60.

When θ₅=90°, the following equations (6) and (7) may be derived from the expression (5).

$${θ}_{2} = arc sin \frac{{n}_{5}}{{n}_{2}} \qquad ( 6 )$$

$${θ}_{1} = arc sin \frac{{n}_{5}}{{n}_{1}} \qquad ( 7 )$$

As can be seen from equations (6) and (7), the refractive index of the auxiliary layer 60 determines the maximum exit angle of light that can be incident on the encapsulation organic layer 32. Due to a lower refractive index of the auxiliary layer 60, the maximum exit angle of the light that can be incident on the encapsulation organic layer 32 is relatively small. In other words, the auxiliary layer 60 is provided such that light exiting from the first inorganic layer 31 at a larger exit angle may be locked within the interface between the first inorganic layer 31 and the auxiliary layer 60 as much as possible, to prevent these light from entering the color conversion portion corresponding to the adjacent light-emitting structure 201.

In an exemplary embodiment, the auxiliary layer 60 may be made of MgF₂ with a refractive index of 1.38, and a critical angle of total reflection for light incident on the auxiliary layer 60 is 50°. That is, any light emitted from the first inorganic layer 31 at an exit angle greater than 50° may not exit from the first inorganic layer 31. Compared with a scheme in which the auxiliary layer 60 is not provided, the auxiliary layer 60 can reduce the exit angle of the light emitted from the first inorganic layer 31, which helps to reduce the degree of cross-color between adjacent light-emitting structures 201.

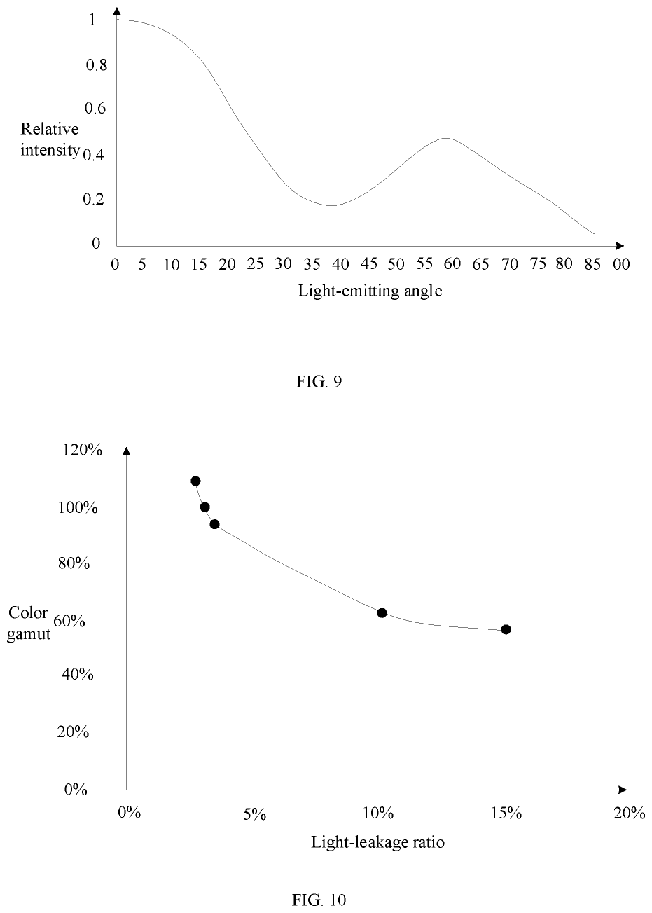

FIG. 9 is a graph illustrating light intensity versus light-emitting angle of blue light emitted by a light-emitting structure. As can be seen from FIG. 9, light with the light-emitting angle between 50° and 56° has a relatively high light intensity. The auxiliary layer 60 is provided to prevent this part of the light from entering the color conversion portion corresponding to the adjacent light-emitting structure, thereby effectively reducing the degree of cross-color between adjacent light-emitting structures 201.

The graph shown in FIG. 10 was obtained by simulating and analyzing a change in a color gamut of a device with different light-leakage ratios. The light-leakage ratio refers to a ratio of a total energy of light emitted by a light-emitting structure that is incident on a color conversion portion corresponding to an adjacent light-emitting structure to a total energy of the light emitted by the light-emitting structure. As can be seen from FIG. 10, in order to improve the color gamut of the device, the light-leakage ratio may be reduced. By reducing the total energy of the light emitted by the light-emitting structure that is incident on the color conversion portion corresponding to the adjacent light-emitting structure, the light-leakage ratio may be reduced. In the embodiment shown in FIG. 4, by providing the auxiliary layer, the light-leakage ratio can be effectively reduced, and thus the color gamut of the device can be improved.

In an exemplary embodiment, the display panel includes the auxiliary layer 60 located between the first inorganic layer 31 and the encapsulation organic layer 32. The auxiliary layer 60 may be made of MgF₂ with a refractive index of 1.38, and a critical angle of total reflection for light incident on the auxiliary layer 60 is 50°. When the width of the shading portion 42 varies, the minimum cross-color angle, a cross-color ratio (a ratio of the amount of light emitted by a light-emitting structure that causes cross-color to a total amount of the light emitted by the light-emitting structure), and the width of the shading portion 42 of the display panel are shown in Table 1 below.

TABLE 1

| | Width of the | |
|---|---|---|
| Minimum cross-color angle | shading portion/μm | Cross-color ratio |
| 25° | 9.2 | 24% |
| 35° | 14.9 | 11% |
| 45° | 25.6 | 5.5% |

If the auxiliary layer 60 is not provided in the display panel, and a refractive index of the encapsulation organic layer 32 is 1.5, a critical angle of total reflection for light incident on the encapsulation organic layer 32 is 56°. When the width of the shading portion 42 varies, a cross-color angle, a cross-color ratio, and the width of the shading portion 42 of the display panel are shown in Table 2 below.

TABLE 2

| | Width of the | |
|---|---|---|
| Cross-color angle | shading portion/μm | Cross-color ratio |
| 25° | 9.2 | 29% |
| 35° | 14.9 | 19% |
| 45° | 25.6 | 12% |

Comparing Table 1 and Table 2, it can be seen that by providing the auxiliary layer 60, the cross-color ratio can be effectively reduced, and thus the color gamut of the device can be improved.

In a further embodiment, referring to FIG. 5, the organic layer in direct contact with the auxiliary layer 60 is provided with one or more hollow portions, in which the auxiliary layer 60 is disposed. The auxiliary layer 60 includes a plurality of auxiliary portions 62, each of which is disposed in a respective hollow portion of the organic layer. In this way, the auxiliary layer 60 is provided such that a thickness of the display panel may not be increased.

In some embodiments, the organic layer in direct contact with the auxiliary layer 60 is the adhesive layer 34, and the adhesive layer 34 is in direct contact with the color conversion layer 40. The adhesive layer 34 is provided with the hollow portions, and the plurality of auxiliary portions 62 of the auxiliary layer are disposed within the hollow portions of the adhesive layer, respectively.

In an embodiment, the orthographic projection of the auxiliary layer 60 on the base substrate 10 coincides with an orthographic projection of the shading portions 42 on the base substrate 10. The orthographic projection of the auxiliary layer 60 on the base substrate 10 coincides with the orthographic projection of the shading portions 42 on the base substrate 10, which means that the orthographic projection of the auxiliary layer 60 on the base substrate 10 substantially coincides with the orthographic projection of the shading portions 42 on the base substrate 10. The width of the shading portion 42 on a side close to the base substrate 10 is greater than that of the shading portion 42 on a side away from the base substrate 10, and the width of the shading portion 42 on the side close to the base substrate 10 is equal to that of the orthographic projection of the corresponding auxiliary layer 60 on the base substrate 10. This can not only avoid cross-color resulting from part of light emitted by a light-emitting structure entering a color conversion portion corresponding to an adjacent light-emitting structure in the case that an area of the orthographic projection of the auxiliary layer 60 on the base substrate 10 is smaller than that of the orthographic projection of the shading portions 42 on the base substrate 10, but also avoid a reduction in an effective light-emitting area of the display panel in the case that the area of the orthographic projection of the auxiliary layer 60 on the base substrate 10 is larger than that of the orthographic projection of the shading portions 42 on the base substrate 10.

In an embodiment, the auxiliary layer 60 and the adhesive layer 34 have the same thickness. In other embodiments, the auxiliary layer 60 and the adhesive layer 34 may have different thicknesses.

In an embodiment, the material of the auxiliary layer 60 includes nitrogen or an inert gas. When the color conversion module and the display module, after prepared, are bonded together, in order to protect the color conversion module and the display module from invasion of water and oxygen in the air, the color conversion module and the display module are generally bonded together in a nitrogen or inert gas environment, during which the nitrogen or inert gas may enter the hollow portions of the adhesive layer 34 such that the auxiliary layer 60 may be obtained. In this way, preparation of the auxiliary layer 60 may not increase process complexity, and the nitrogen or inert gas has a lower refraction, which is more helpful to reduce the degree of cross-color in the display panel.

In other embodiments, the material of the auxiliary layer includes at least one of a metal fluoride, or a substituted or unsubstituted polyacrylate. In the process of preparing the color conversion module, after the filter layer 70 is formed, the auxiliary layer may be first formed and then the adhesive layer; or the adhesive layer may be first formed and then the auxiliary layer.

In an exemplary embodiment, when light emitted from an edge of a light-emitting structure 201 enters a color conversion portion corresponding to an adjacent light-emitting structure 201, the minimum incident angle of the light incident to the first inorganic layer 31 is the minimum cross-color angle θ₁, an incident angle of the light incident to the encapsulation organic layer 32 is θ₂, an incident angle of the light incident to the second inorganic layer 33 is θ₃, and an incident angle of the light incident to the auxiliary layer 60 is θ₅. The first inorganic layer 31 has a refractive index n₁ and a thickness d₁. The encapsulation organic layer 32 has a refractive index n₂ and a thickness d₂. The second inorganic layer 33 has a refractive index n₃ and a thickness d₃. The auxiliary layer 60 has a refractive index n₅. A distance between two adjacent pixel openings on a side facing away from the base substrate 10 is W₁, a width of the shading portion 42 on a side facing the base substrate 10 is W₂, and a distance between an edge of the pixel opening on a side facing away from the base substrate 10 and an edge of a corresponding shading portion 42 away from that pixel opening is W₃, where the corresponding shading portion 42 to the pixel opening refers to a shading portion adjacent to the color conversion portion corresponding to the pixel opening and close to that edge of the pixel opening. Light is totally reflected upon incident on the auxiliary layer 60. The refractive indices and thicknesses of individual film layers and the incident angles of light, as well as W₁, W₂, and W₃ satisfy the following relational expression (8) and equation (9).

$${n}_{1} sin {θ}_{1} = {n}_{2} sin {θ}_{2} = {n}_{3} sin {θ}_{3} = {n}_{5} sin {θ}_{5} \qquad ( 8 )$$

$${W}_{3} = \frac{{W}_{1} + {W}_{2}}{2} = {d}_{1} tan {θ}_{1} + {d}_{2} tan {θ}_{2} + {d}_{3} tan {θ}_{3} \qquad ( 9 )$$

In the case that the refractive index n₁ of the first inorganic layer 31 is 1.8, the refractive index n₂ of the encapsulation organic layer 32 is 1.5, and θ₂ is 90°, θ₁ may be calculated as 56° from the equation (8). That is, the light emitted by the light-emitting structure with an exit angle greater than 56° may be totally reflected at an interface between the first inorganic layer 31 and the encapsulation organic layer 32.

The refractive index n₃ of the second inorganic layer 33 is 1.9, and the refractive index n₅ of the auxiliary layer 60 is 1 when it is nitrogen. In this case, a critical angle for total reflection of light at an interface between the second inorganic layer 33 and the auxiliary layer 60 may be calculated as 31.7° from the equation (8), that is, θ₅=31.7°. When θ₅=31.7°, θ₁ may be calculated as 33.7° from the equation (8).

Therefore, when an exit angle of light emitted from an edge of a light-emitting structure is in the range of 33.7° to 56°, cross-color between adjacent light-emitting structures may be avoided. However, a range of an angle of light incident to the encapsulation organic layer 32 through the first inorganic layer 31 becomes 0° to 90°. Therefore, regardless of the width of the shading portion, it is impossible to prevent cross-color between adjacent light-emitting structures. However, when θ₁ is less than a certain value, cross-color between adjacent light-emitting structures has less effect on the color gamut of the display panel. For example, when a value of the color gamut of the display panel is within +5% of a value of a color gamut of an ideal display panel, it is considered that the color gamut of the display panel meets requirements. The ideal display panel refers to a display panel with no color-cross between adjacent light-emitting structures.

When W₁=11.2 μm and W₂=20 μm, results obtained by simulating display panels with different structures are shown in Table 3.

TABLE 3

| | | Utilization |
|---|---|---|
| Structure of display panel | Color gamut | of blue light |
| Ideal display panel | 103% NTSC | — |
| Display panel without auxiliary layer | 48% NTSC | 33.9% |
| Display panel with auxiliary | 100% NTSC | 33.8% |
| layer made of N₂ | | |

As can be seen from Table 3, by disposing the auxiliary portion in the hollow portion of the adhesive layer, the degree of cross-color between adjacent pixels can be significantly reduced without loss of blue light, and the color gamut of the display panel can be effectively improved, such that the color gamut of the display panel can meet the requirements.

Embodiments of the present application further provide a display apparatus, including the display panel according to any one of the above embodiments.

In an embodiment, the display apparatus further includes: a driver configured to provide a drive signal to drive the light-emitting structure to emit light; and a power supply circuit configured to supply power to the display panel.

In an embodiment, the display apparatus further includes a housing in which the display panel is disposed.

The display apparatus according to embodiments of the present application may include, for example, a mobile phone, a tablet computer, a television, a notebook computer, a vehicle-mounted device, and any other device with a display function.

It should be noted that in the drawings, sizes of layers and areas may be exaggerated for clarity of illustration. Furthermore, it may be understood that when an element or layer is referred to as being “on” another element or layer, it may be directly on the other element, or there may be an intermediate layer. Further, it may be understood that when an element or layer is referred to as being “under” another element or layer, it may be directly under the other element, or more than one intermediate layer or element may be present. In addition, it may be understood that when a layer or element is referred to as being “between” two layers or elements, it may be the only layer between the two layers or elements, or more than one intermediate layer or element may be present. Similar reference numerals indicate similar elements throughout.

Other embodiments of the present application will be apparent to those skilled in the art from consideration of the specification and practice of the disclosure disclosed herein. The present application is intended to cover any variations, uses, or adaptive changes of the present application that follow general principles thereof and include common knowledge or conventional technical means in the art that are not disclosed in the present application. The specification and embodiments are considered as exemplary only, with a true scope and spirit of the present application being indicated by the following claims.

It should be understood that the present application is not limited to the precise structures that have been described above and shown in the drawings, and that various modifications and changes may be made without departing from the scope thereof. The scope of the present application is limited only by the appended claims.

1. A display panel, comprising:
a base substrate;
a light-emitting layer located on the base substrate, and comprising a plurality of light-emitting structures arranged at intervals;
an insulating material structure located on a side of the light-emitting layer facing away from the base substrate, and comprising organic and inorganic layers arranged alternately;
a color conversion layer located on a side of the insulating material structure facing away from the base substrate, and comprising a plurality of color conversion portions with a shading portion located between adjacent color conversion portions; and
an auxiliary layer having an orthographic projection on the base substrate covering an orthographic projection of the shading portion on the base substrate, the auxiliary layer being in direct contact with adjacent organic and inorganic layers in the insulating material structure, respectively, and the auxiliary layer having a refractive index that is less than a refractive index of the organic layer in direct contact with the auxiliary layer and less than a refractive index of the inorganic layer in direct contact with the auxiliary layer.

2. The display panel according to claim 1, wherein
the insulating material structure comprises an encapsulation layer, and the encapsulation layer comprises at least two inorganic layers and at least one organic layer; and
the auxiliary layer is located between the organic layer of the encapsulation layer and the inorganic layer provided on a side of the organic layer close to the base substrate.

3. The display panel according to claim 2, wherein the encapsulation layer comprises a first inorganic layer, an encapsulation organic layer located on the first inorganic layer, and a second inorganic layer located on the encapsulation organic layer, the first inorganic layer is in direct contact with the light-emitting structures, and the auxiliary layer is located between the first inorganic layer and the encapsulation organic layer.

4. The display panel according to claim 1, wherein
the auxiliary layer is located between adjacent organic and inorganic layers in the insulating material structure; and
the orthographic projection of the auxiliary layer on the base substrate covers an orthographic projection of the color conversion layer on the base substrate.

5. The display panel according to claim 1, wherein the refractive index of the auxiliary layer is less than or equal to 1.4.

6. The display panel according to claim 1, wherein the organic layer in direct contact with the auxiliary layer is provided with one or more hollow portions, in which the auxiliary layer is disposed.

7. The display panel according to claim 6, wherein the organic layer in direct contact with the auxiliary layer is an adhesive layer, and the adhesive layer is in direct contact with the color conversion layer.

8. The display panel according to claim 6, wherein the orthographic projection of the auxiliary layer on the base substrate coincides with the orthographic projection of the shading portion on the base substrate.

9. The display panel according to claim 7, wherein the auxiliary layer and the adhesive layer have a same thickness.

10. The display panel according to claim 6, wherein a material of the auxiliary layer comprises nitrogen or an inert gas.

11. The display panel according to claim 1, wherein a material of the auxiliary layer comprises at least one of a metal fluoride, or a substituted or unsubstituted polyacrylate.

12. The display panel according to claim 1, wherein the auxiliary layer comprises a photonic crystal structure, which comprises a plurality of columnar structures arranged in an array.

13. The display panel according to claim 12, wherein a first distance between centers of adjacent two of the columnar structures ranges from 100 nm to 300 nm.

14. The display panel according to claim 13, wherein a minimum distance between adjacent two of the columnar structures is a second distance, and a ratio of a difference between the first distance and the second distance to the first distance ranges from 0.2 to 0.8.

15. The display panel according to claim 1, wherein the color conversion portions correspond to the light-emitting structures one-to-one, and an orthographic projection of the color conversion portions on the base substrate covers an orthographic projection of the light-emitting structures on the base substrate.

16. The display panel according to claim 15, wherein
each of the light-emitting structures in the light-emitting layer emits blue light; and
the color conversion portion comprises: a red color conversion portion comprising a red quantum dot and a light-scattering particle; a green color conversion portion comprising a green quantum dot and a light-scattering particle; and a light-transmissive portion comprising a light-scattering particle.

17. The display panel according to claim 1, further comprising a filter layer located on a side of the color conversion layer facing away from the base substrate,
wherein the filter layer comprises a black matrix and a plurality of filter portions, the plurality of filter portions correspond to the plurality of light-emitting structures one-to-one, and the orthographic projection of the shading portion on the base substrate coincides with an orthographic projection of the black matrix on the base substrate.

18. A display apparatus, comprising a display panel, wherein the display panel comprises:
a base substrate;
a light-emitting layer located on the base substrate, and comprising a plurality of light-emitting structures arranged at intervals;
an insulating material structure located on a side of the light-emitting layer facing away from the base substrate, and comprising organic and inorganic layers arranged alternately;
a color conversion layer located on a side of the insulating material structure facing away from the base substrate, and comprising a plurality of color conversion portions with a shading portion located between adjacent color conversion portions; and
an auxiliary layer having an orthographic projection on the base substrate covering an orthographic projection of the shading portion on the base substrate, the auxiliary layer being in direct contact with adjacent organic and inorganic layers in the insulating material structure, respectively, and the auxiliary layer having a refractive index that is less than a refractive index of the organic layer in direct contact with the auxiliary layer and less than a refractive index of the inorganic layer in direct contact with the auxiliary layer.

19. The display apparatus according to claim 18, wherein
the insulating material structure comprises an encapsulation layer, and the encapsulation layer comprises at least two inorganic layers and at least one organic layer; and
the auxiliary layer is located between the organic layer of the encapsulation layer and the inorganic layer provided on a side of the organic layer close to the base substrate.

20. The display apparatus according to claim 18, wherein the organic layer in direct contact with the auxiliary layer is provided with one or more hollow portions, in which the auxiliary layer is disposed.
